(19) United States
(12) Patent Application Publication
(10) Pub. No.: US 2014/0299174 A1
(43) Pub. Date: Oct. 9, 2014

(54) SYSTEM OF GEOTHERMAL COOLING FOR PHOTOVOLTAIC SOLAR PANELS AND APPLICATION THEREOF

(71) Applicants: Kenneth Keung Yum Yu, Hong Kong (CN); Dato'Michael Loh, Sg (SG); Siu Keun Tsang, Saratoga, CA (US)

(72) Inventors: Kenneth Keung Yum Yu, Hong Kong (CN); Dato'Michael Loh, Sg (SG); Siu Keun Tsang, Saratoga, CA (US)

(21) Appl. No.: 14/240,747

(22) PCT Filed: Aug. 23, 2012
(86) PCT No.: PCT/IB2012/054263

§ 371 Date: Jun. 9, 2014

Related U.S. Application Data
(60) Provisional application No. 61/527,120, filed on Aug. 25, 2011.

(51) Int. Cl. H01L 31/052

(52) U.S. Cl. CPC H01L 31/0521
USPC 136/246

(57) ABSTRACT

The instant invention provides a geothermal cooling system for cooling semiconductor PV panels operating in either concentrating or non-concentrating mode, which comprises heat sink mounted onto the underside of the silicon PV panel, a subterranean-level condenser, and other necessary equipment. Different embodiments of the geothermal cooling system are also provided in this invention.

### CROSS-REFERENCE TO RELATED APPLICATION

This application claims benefit under 35 U.S.C. §119(e) of U.S. Provisional Application having Ser. No. 61/527120, filed on Aug. 25, 2011, which is hereby incorporated by reference herein in its entirety.

### FIELD OF INVENTION

This invention relates to device novel method for cooling solar panels, and in particular the use of geothermal heat exchange in such cooling method.

### BACKGROUND OF INVENTION

Given the rapid rise of oil price, and evidence of peak oil production looming ahead, governments and industries have started to develop alternative energy source in earnest. The recent nuclear disaster in Fukushima added to the urgency of adoption of the types of renewable energy generation which warrant high safety factor to human with higher output efficiency.

Solar energy has been regarded as one of the most promising renewal energies which is safe to both the human and the environment. Photovoltaic (PV) solar technology, represented by silicon solar panels, CdTe solar panels, and others, is a well-developed technology in this aspect, with many solar farms operating worldwide producing many hundreds of mega Watt of electricity routinely. Under the sun, an non-concentrating solar panel heats up to a much higher temperature (30 to 60 degrees Celsius) than ambiance, and concentrating solar panel heats up to much higher temperature, maybe well over 100 degrees Celsius. It is also known that high temperature degrades performance of solar cells substantially. Both theory and measurement indicate a maximum power output temperature coefficient of 0.4-0.5% per degree Celsius. To achieve a lower operating temperature for the PV panel by any means will give a significant higher efficiency. Air cooling by finned heat sink is inefficient, and conventional refrigeration is costly and not cost-efficient.

### SUMMARY OF INVENTION

In the light of the foregoing background, it is an object of the present invention to provide an alternate method for efficiently lowering the operation temperature of solar panels to increase the output efficiency thereof.

Accordingly, the present invention, in one aspect, is a closed-loop geothermal cooling system that uses non-phase change heat transfer fluid to transport heat from an operating PV panel to subterranean level; the system comprises:

a). a heat sink mated securely and thermally to an underside of the PV panel by a thermal interface material, in which the heat sink further comprises a plurality of inlet and/or outlet connectors, and a plurality of built-in ducts;

b). a buried subterranean-level condenser comprising a plurality of vertical, horizontal or hybrid loops; and

c). a circulating pump adapted to power said heat transfer fluid around the loop.

In an exemplary embodiment, the non-phase change heat transfer fluid is an air-water mixture or other appropriate mixtures. In another exemplary embodiment, the PV panel is made of silicon, CdTe, or other semiconductors. In yet another exemplary embodiment, the PV panel comprises sunlight concentrators.

According to another aspect of the present invention, a closed-loop geothermal cooling system using phase change heat transfer fluid to transport heat from an operating PV panel to subterranean level is provided which comprises:

a). a heat sink mated securely and thermally to an underside of the PV panel by a thermal interface material, in which the heat sink comprises a plurality of inlet and outlet connectors, and a plurality of built-in ducts;

b). a buried subterranean level condenser comprising a plurality of vertical or horizontal loops;

c). a compressor pump adapted to move the vaporized heat transfer fluid from the heat sink to the subterranean level condenser; and

d). an expansion valve adapted to reduce the pressure of the heat transfer fluid when the heat transfer fluid passes through the expansion valves.

In an exemplary embodiment, the phase change heat transfer fluid is refrigerant. In another exemplary embodiment, the PV panel is made of silicon, CdTe, or other semiconductors. In a further another exemplary embodiment, the PV panel comprises sunlight concentrators. In yet another embodiment, the heat sink is an evaporator.

In a further aspect of the present invention, a geothermal cooling system is provided which comprises:

a). a circulating pump adapted to pass water from a body of water to an array(s) of PV panels; and

b). a heat sink mated securely and thermally to an underside of the silicon PV panel by a thermal interface material, in which the heat sink further comprises a plurality of inlet and/or outlet connectors, and a plurality of inlet and/or outlet connectors, and a plurality of built-in ducts; and that the water transports away the heat from the PV panels through the heat sink.

The geothermal cooling system is adapted to be used for a solar farm located in close proximity to the body of water. The system is operated under an open-loop or closed-loop design.

In an exemplary embodiment of the present invention, the heated water leaving the heat exchanger is channeled into stream chambers of stream turbines or electrolysis chambers. In another exemplary embodiment, the PV panel is made of silicon, CdTe, or other semiconductors. In yet another exemplary embodiment, the PV panel comprises sunlight concentrators.

In another aspect of this invention, a geothermal cooling system is provided which comprises:

a). a circulating pump adapted to pass cool water from a body of water to an array(s) of PV panels; and

b). a spray nozzle adapted to spray cool water onto a backside of said PV panels for transporting heat away from the PV panels;

The geothermal cooling system is adapted to be used for a solar farm located in close proximity to the body of water and is operated under an open-loop design.

In another exemplary embodiment, the PV panel is made of silicon, CdTe, or other semiconductors. In yet another exemplary embodiment, the PV panel comprises sunlight concentrators.

There are many advantages to the present invention. For instance, GHE generates more energy (i.e. heat removed) than consumed by the electric motor. A cooled PV panel delivers more power. Both factors contribute to much more energy output per solar PV panel for a given area of solar farm.

The prospect for solar energy as a major alternative renewable energy source has never been better. Both mega-Watt class power plant (on grid), and off grid roof mounted solar power plants have been demonstrated. Even though solar energy is relatively costly compared with oil, or nuclear power, mass adoption of solar plants and the promising technical development brought along by the instant invention will drive the ramp up of solar power, at an ever decreasing cost.

Further, the instant invention invokes mostly off the shelf technology, and is compatible with present PV panel and solar farm construction work flow. Since the GHE system uses the same real estate as the solar farm, no additional land is required.

### BRIEF DESCRIPTION OF FIGURES

FIG. 1 is a diagram showing the arrangement of typical PV panel arrays in a solar farm operating in the sunny region.

FIG. 2a shows a top schematic view of the layout of PV panel arrays in the solar farm, where the matrix layout of rows upon rows of PV panels is clearly visible. FIG. 2b shows one row of the PV solar panel arrays connected to GHE structures (optional) for additional cooling and a power conversion station (PCS) for power conversion, collection and storage.

FIG. 3 illustrates the key components of a PV panel module composition according to one embodiment of the instant invention.

FIG. 4 shows multiple PV panels attached to a cooling loop according to one embodiment of the instant invention.

FIG. 5a shows the vertical thermal exchange loop design of the geothermal cooling system according to the same embodiment of the instant invention. FIG. 5b shows two different horizontal thermal exchange loop designs of the geothermal cooling system according to the same embodiment of the instant invention.

FIG. 6 illustrates a schematic diagram of a geothermal cooling system according to another embodiment of the instant invention.

FIG. 7 illustrates a schematic diagram of another design of the geothermal cooling system according to the same embodiment of the instant invention.

FIG. 8 illustrates a schematic diagram of the geothermal cooling system according to one embodiment of the instant invention.

FIG. 9 illustrates a schematic diagram of another design of the geothermal cooling system according to the same embodiment of the instant invention.

FIG. 10a shows a cross-sectional diagram of a geothermal cooling system according to another embodiment of the instant invention. FIG. 10b illustrates a schematic diagram of the same embodiment of the instant invention.

### DETAILED DESCRIPTION OF THE PREFERRED EMBODIMENTS

As used herein and in the claims, “comprising” means including the following elements but not excluding others.

The instant invention uses the heat reservoir property of the underground to achieve efficient cooling of solar panels. It couples key feature of the PV technology, and Geothermal Heat Exchange (GHE) technology to achieve much higher power output, for any given solar panel surface area, or solar farm area. It is also broadly applicable to all semiconductor solar panels including silicon, CdTe, and others; and concentrating PV (CPV) solar farms in which sunlight concentrators are applied in the CPV solar farms.

GHE system is one of the well-developed and cost-efficient cooling technologies. The subterranean layer of the earth's crust is an immense heat reservoir, and the underground temperature (3 meters or more below ground) of most of the earth's surface is held at a relatively constant temperature of around 10 degrees Celsius. Geothermal technology utilizes this constant temperature heat bath to achieve a Carnot Cycle heating and cooling of desired above ground structures. Well-designed GHE systems can achieve a Coefficient of Performance (COP)—ratio of energy output (heat removed) to energy input (electricity consumed by pump, and compressor)—on the order of 3 to 6. GHE system is therefore net energy positive. Most GHE systems are conventionally used to heat up or cool down buildings or other enclosed space.

In general, in the instant invention, a GHE system is designed to direct a cooling fluid flowing through a heat sink mounted on the backside of the PV panel. The power output of a PV panel increases by 0.4-0.5% per degree. The cooling fluid is then directed underground, where it is cooled by the much lower underground temperature. This geothermal cooling of the PV panel results in an increased energy output for a given amount of sunlight. Also, the operating temperature of the PV panel illuminated by strong sunlight is thus lowered by employing a GHE system.

Subterranean (3 meters or more below ground) ground temperature is remarkably constant around the world (5-15 degree Celsius), and more importantly, the heat capacity is virtually unlimited. Meanwhile, a non-concentrating operating PV panel under cloudless sky heats up rapidly to equilibrium in less than 30 minutes. In moderate climate, with 12 degree C. ambient, PV panel heats up to 50 degree C. or more. In the desert or at the equator, the temperature inside a PV solar panel can climb up to 70 degree C. or more. We can therefore assume a temperature difference of between 30 to 60 degrees C. between panel and ground. This delta temperature is more than enough to set up a Carnot cycle of cooling. Concentrating Photovoltaic system, with multiple suns equivalent irradiation, the temperature difference can be much higher, perhaps over 100 degrees C.

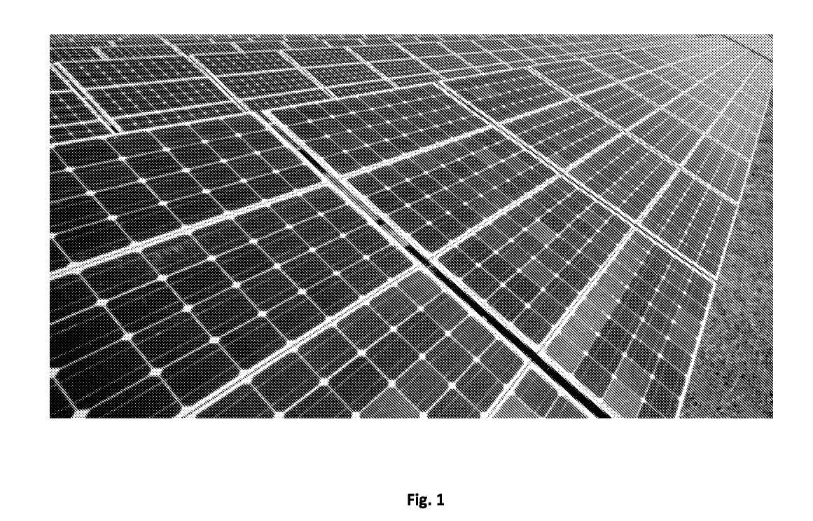

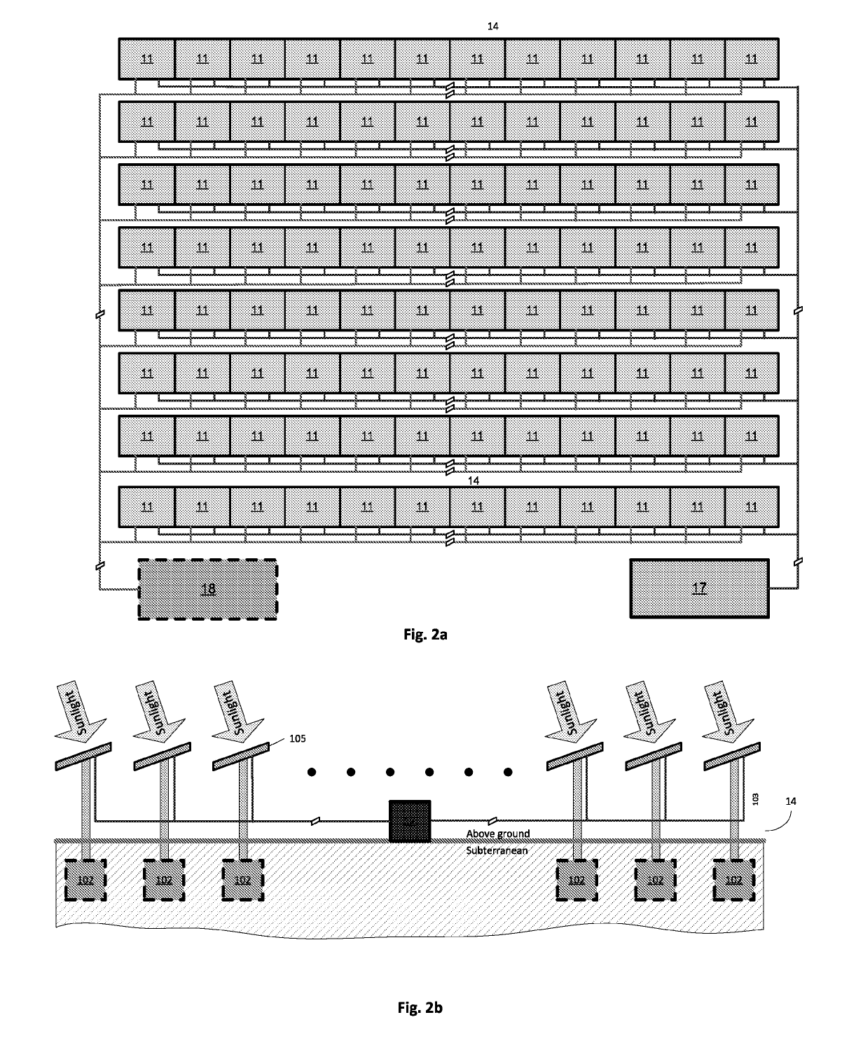

Referring first to FIG. 1 which shows the arrangement of typical PV panel arrays in a solar farm operating in the sunny region. FIG. 2a shows a top schematic view of the layout of PV panel arrays in the solar farm, where the matrix layout of rows upon rows 14 of PV panels 11 is clearly visible. An optional thermal exchange system 18 and a power conversion station (PCS) 17 are also shown to connect to the PV panel arrays. FIG. 2b shows one row 14 of PV panel arrays connected to subterranean GHE structures 102 (optional) for additional cooling and a PCS 17 for power conversion, collection and storage. Within each row 14 of PV panels, the PV panel module 105 is in close proximity, stretching over a long distance, and stacked three to four deep. There is plenty of room beneath the PV panel module 105 to mount cooling pipes, pumps and other equipment.

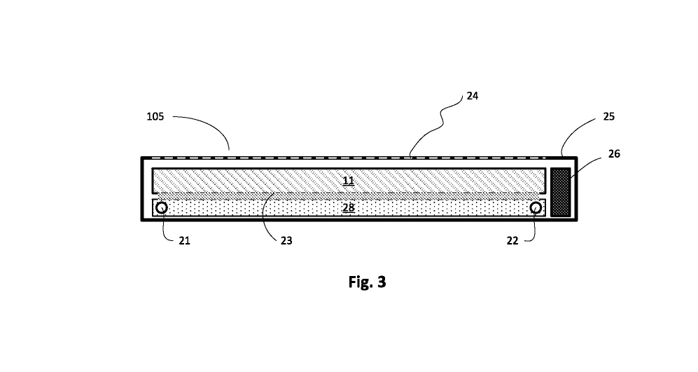

In FIG. 3, a PV panel module 105 is shown in which a PV panel 11 and a heat sink 28, sandwiching a thermal interface material (TIM) 23, are equipped within a housing enclosure 25. A transparent layer with anti-reflective coating painted thereon 24 is installed on the side of the housing enclosure 25 facing sunlight. In one exemplary embodiment, the thermal conductive material 23 is a TIM. Inlet 21 and outlet 22 are also equipped in each PV panel module 105 for connecting adjacent PV panel modules 105. An electrical box 26 is also installed within housing enclosure 25.

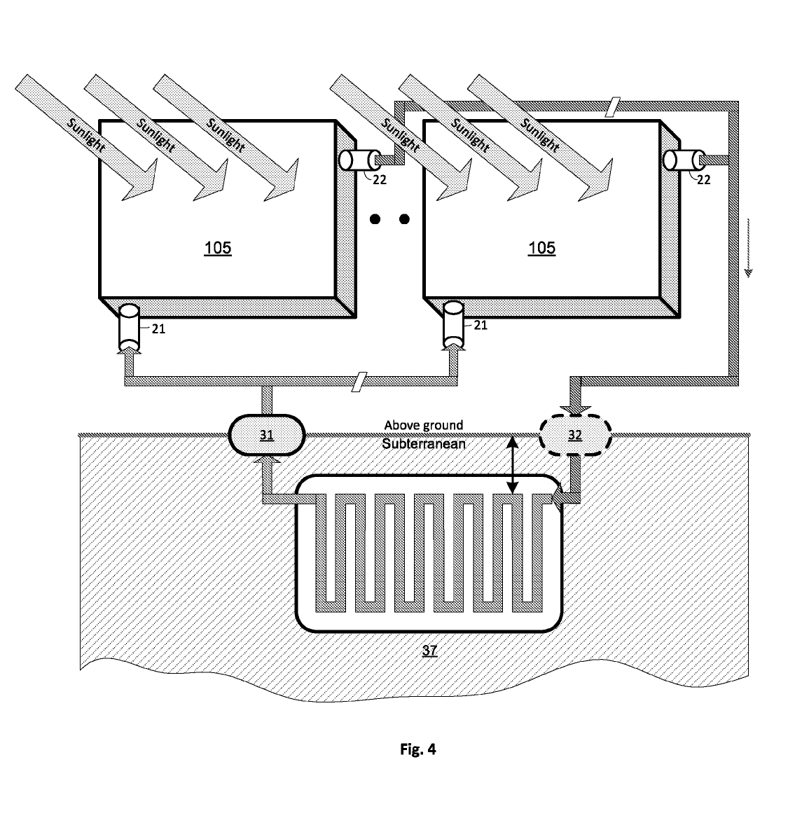

An example of the first embodiment of this invention is shown in FIG. 4. Two PV panels 11 are shown to connect to each other and attach to a cooling loop in this example. In actual implementation, a number of PV panels 11 can be cooled in parallel. In this example, unnecessary equipment such as secondary heating loops, extra pumps, etc is deleted for clarity of explanation and only the most important components are illustrated.

Operating in bright sunlight, a PV panel without surface treatment will absorb up to 60% of the solar energy over broad band, and will heat up rapidly. The basic reason is that air is a poor heat conductor, and the only way for the panel to dissipate its heat is by blackbody radiation. This is possible only when the panel is at a significantly higher temperature than the ambience. In the normal operation of a solar panel, equilibrium is reached when the energy radiated by the panel equals the absorbed energy from the sun. In the present embodiment, an additional cooling mechanism is set up to bring the PV panel temperature down. The cooling fluid flowing in the heat sink will conduct the heat away by convection.

As is evident from FIG. 4, this example of the first embodiment features a closed loop design. The loop comprises the integral solar panel modules 105 and a buried subterranean-level condenser 37, thermally insulated conducting pipes, and the circulating pump. Electricity supply for the pump comes from external source. The pumps move the cooling fluid around the loop. After the cooling fluid picks up heat from the heat exchanger installed within the solar panel module 105 (an example of such arrangement is demonstrated in FIG. 3), it is moved to the condenser 37. In the underground condenser 37, the fluid temperature is once again brought close to the ground temperature. Then the entire cooling cycle is ready to start again. In one exemplary embodiment, a two-pump system comprising a push-pump 31 and a pull-pump 32 can be used to increase fluid flow efficiency and deliver a higher COP (coefficient of performance).

In this embodiment, PV panel module is attached to one end of a geothermal cooling pump, so that heat generated during the operation of the PV panel module can be transported away. This is accomplished by attaching a heat sink to the PV panel with the PV panel module. The heat sink is built of light material that has good thermal conductivity, such as aluminum. It has built-in cooling ducts to allow free flowing cooling fluid, and/or refrigerants. It has an inlet port, and an outlet port to allow incoming and outgoing fluid pipes to be connected. An example of the attachment of the heat sink within the PV panel is demonstrated in FIG. 3.

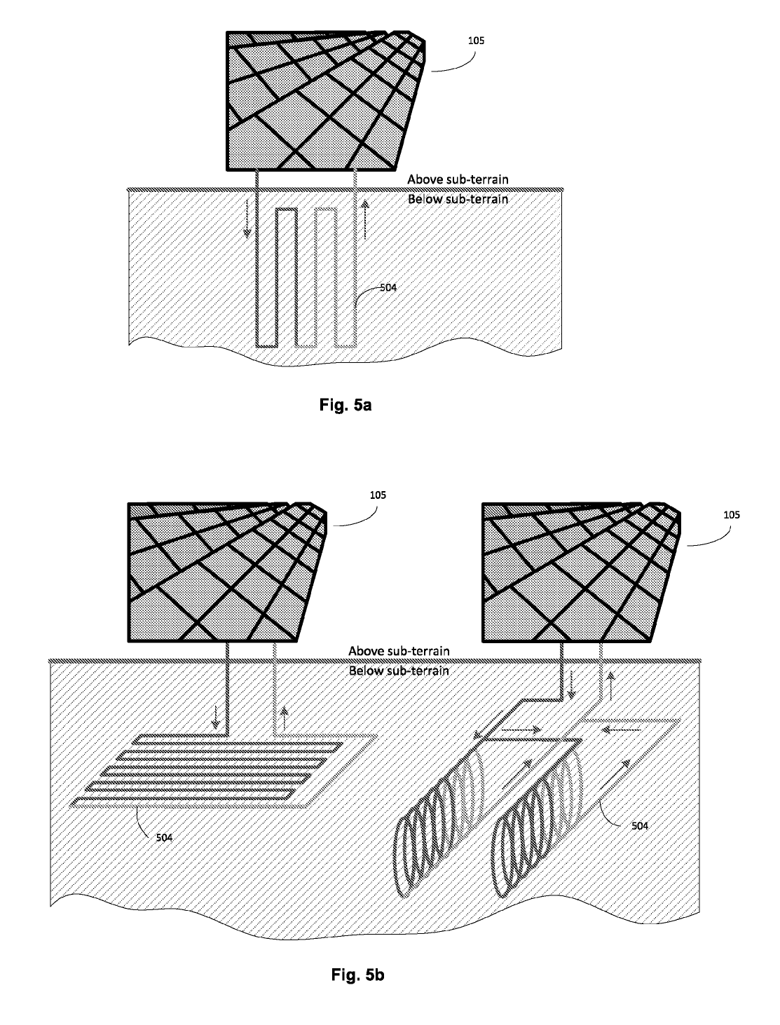

There are three basic designs of the underground condenser which works as a heat exchanger, as shown in FIGS. 5a and 5b. FIG. 5a shows a vertical thermal exchange loop design. In this vertical loop design, an array of deep bore holes up to 100 ft are bored into the ground, and loops of pipes 504 are inserted. When the pipes 504 are in place, the holes are backfilled carefully to retain good thermal conductivity between the cooling pipes 504 and the ground. The vertical loop is the best way to maintain a constant cooling temperature. FIG. 5b shows two different horizontal thermal exchange loop designs. The horizontal loop designs require more real estate, but cost less because ground excavation only goes as deep as 10 ft or so. It does suffer from a day to night temperature swing due to proximity of the ground. However, both vertical loop and horizontal loop designs are well proven in thousands of geothermal heat pump worldwide.

Cost-wise, this first embodiment is the simplest in terms of key components, and cost of installation. The system depicted in FIG. 4 only requires the heat sink, circulation pump, and ground loop condenser to work. Electricity requirement is minimal Water can be used as cooling fluid which is a free source. The cooling fluid heats up in the solar panel, and cools down underground, therefore performs heat transfer from one location to another. However, it is not always the most efficient heat engine, from a thermodynamics point of view. A more efficient heat engine can be built using chemical refrigerant that undergoes phase change, and this is described in second embodiment below.

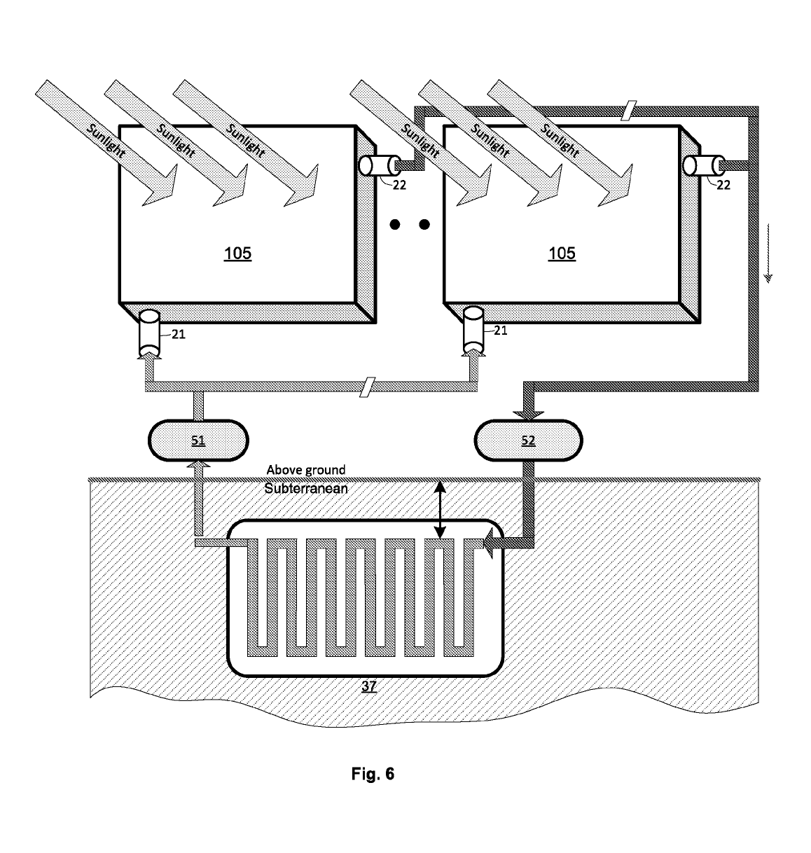

In the second embodiment, phase change refrigerant is used in place of a simple air/water mixture as the heat transfer fluid. A schematic diagram of an example of this second embodiment is shown in FIG. 6. Typical refrigerants are Chlorofluorocarbons (CFC-12, CFC-114, R-500, R-502, etc), or Hydro Chlorofluorocarbons (HFC-134a, HFC-152a, HFC-32, HFC-125/143a, etc), or synthetic mixtures thereof. The use of these refrigerants allows the evaporation temperature, latent heat, specific heat to be engineered to maximize the loop heat transfer efficiency.

The loop operation and the functionality of the key components of this example are described below. Cool (say 5-10 degrees Celsius) liquid refrigerant from the inlet side 21 enters the solar panel heat sink installed within the solar panel module 105. During passage through the ducting of condenser 37, the refrigerant is changed from a low temperature/pressure liquid and vapor mix to a low temperature/pressure vapor through the addition of heat from the solar panel modules 105. This vaporization occurs since the panel temperature level is higher than the boiling temperature of the refrigerant. The vapor then flows to the compressor 52, where it is transformed into a high temperature/pressure vapor, and discharged into the ground loop condenser 37, where the refrigerant gives up its heat to the cooler ground, and condenses back to a warm liquid. The refrigerant liquid then undergoes a temperature/pressure drop by passing through an expansion valve 51. Now the cool refrigerant liquid is ready to go into the solar panel modules 105 and repeats the cycle again.

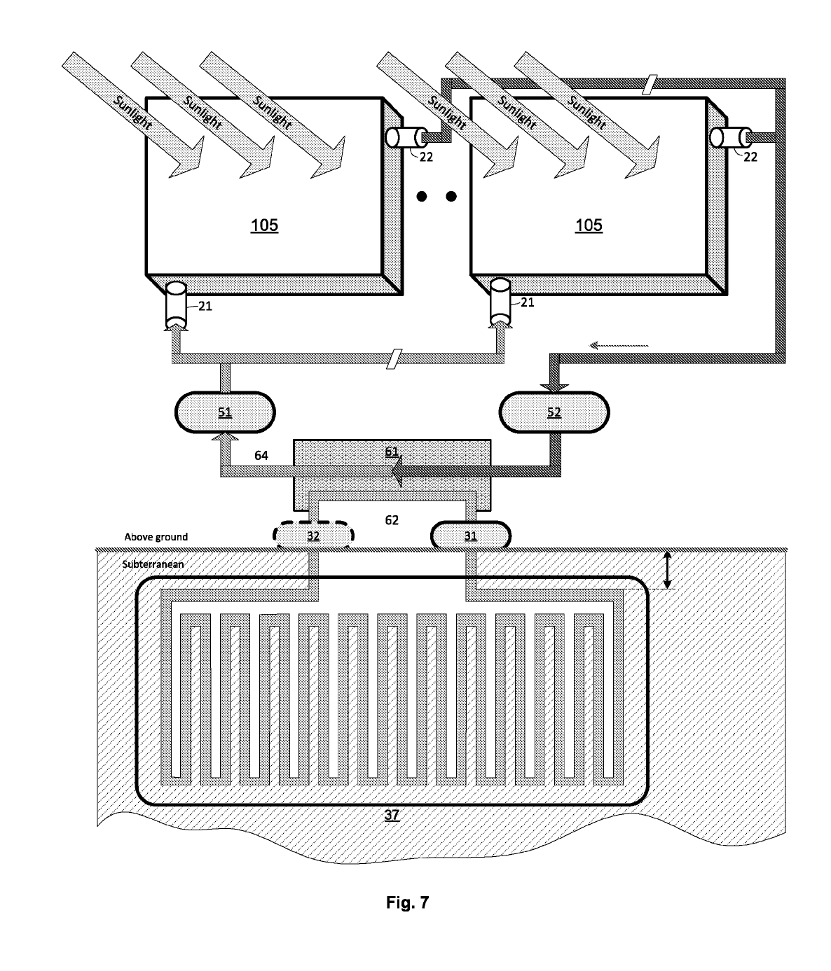

In one variation of this second embodiment, the refrigerant is not circulated directly into the ground loop condenser for two reasons. One is to minimize the amount of refrigerant used by confining it to an above ground cooling loop, and to avoid spillage or leakage of the refrigerant into the subterranean, where it can pollute the soil. An example of such arrangement is demonstrated in FIG. 7. As shown, a thermal exchange coupler 61 is added in the first loop 64 to cool the refrigerant when it comes out of the compressor 52. In the second loop 62 cool air/water mix is drawn from underground pipes to exchange heat with the refrigerant within the thermal exchange coupler 61.

The PV panel heat sink installed within the solar panel module 105 in the second embodiment can be of the same design as that the first embodiment. An example of such arrangement of heat sink within the solar panel module is shown in FIG. 3 and described above. The mounting of the solar panel onto the heat sink can use the same procedure and employs TIM for thermal bonding purpose. In a similar fashion, the ground loop condenser design in the second embodiment can be identical to that in the first embodiment, especially in the two-loop system as depicted by FIG. 7.

The first and second embodiments point out the importance of the thermal design of the PV panel to heat sink interface. For the PV panel to become an integral part of the heat exchanger/evaporator of the geothermal cooling pump, it needs a very efficient thermal path to the heat sink A simple air interface between silicon and aluminum would not be too appropriate since there will be too many microscopic air pockets, and unevenness of the two surfaces, exacerbated by thermal expansion and contraction, which would produce a highly inefficient heat exchanger. This problem was faced up to, and partially solved in the semiconductor industry, in its application of power devices, and later on high power microprocessors.

The afore-described first embodiment and second embodiment are generally applicable to a large area solar farm. Since land is not free, the PV panels are grouped tightly together, and typically try to occupy all available land. This invention allows the geothermal heat pump to be implemented on the same piece of real estate as the solar farm. It works particularly well with the vertical loop condenser design, which occupies far less space than the solar panels. For the first embodiment and the second embodiment, the construction sequence will begin with the sinking of the many bore holes for the vertical loops. Then the loop equipment such as circulating pump, compressor, or expansion will be installed above ground, but underneath the solar panel. FIG. 2b is a schematic illustration of this concept. Another major advantage is that the distance between solar panel arrays, and geothermal cooling loop is absolutely minimized, resulting in little heat loss, and thus improving the thermal efficiency of the loop.

If the solar farm is located near natural water sources, such as underground well, river or lake, a third and/or fourth embodiment of the instant invention utilizing the bodies of water for cooling become feasible.

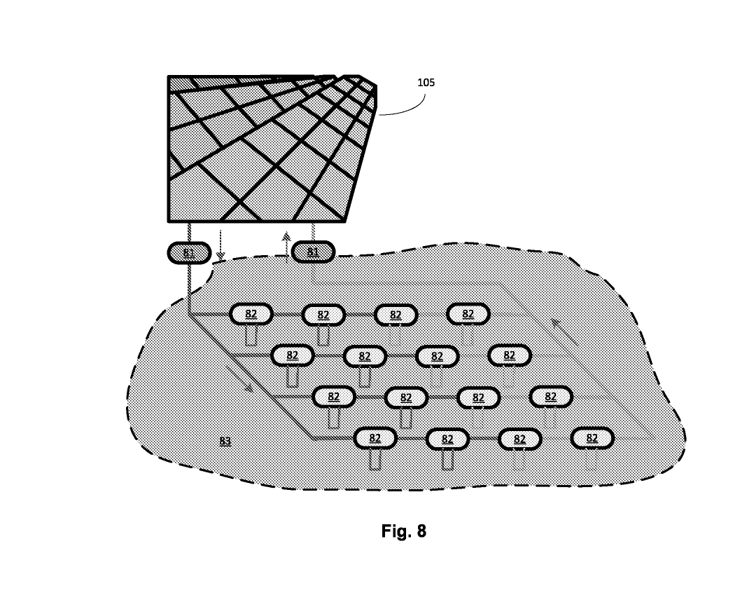

An example of the third embodiment is illustrated in FIG. 8, in which the ground loop condenser (either in horizontal or vertical design) is replaced by a surface water loop. This is still a closed loop design similar to the one described in the first embodiment. The major difference is the use of a body of water 83 as the liquid heat reservoir. Water is a marvelous conductor, and the water temperature a couple of meters beneath the surface is quite low already (0 to 10 degrees C.). The heat sink property of water beneath the surface is even better than the water above the ground. The design of the surface water loops usually has a number of surface flotation buoys 82, with cooling loops that will extend some distance beneath the surface. This arrangement will even work when the surface of the pond, or lake freezes during winter, provided that anti-freezing agent is incorporated into the cooling fluid.

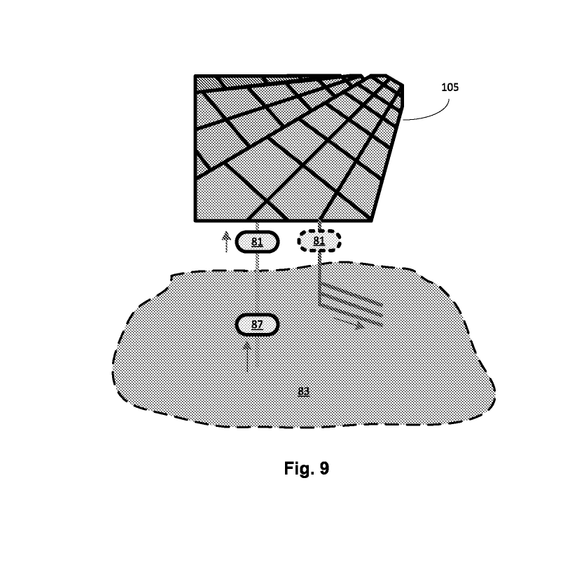

A variation on of this embodiment is an open loop design. An example thereof is demonstrated in FIG. 9, where cool water from the pond or lake 83 is pumped (via pump 81) through the heat exchanger of the solar panels, and then discharged back into the lake some distance away. It will work provided that proper filtration 87 is introduced to in the inlet end of the loop.

In another variation of this embodiment, heated water output from the thermal exchangers in solar panel arrays can be channeled into other chambers—such as stream chambers of the stream turbines in concentrated solar power (CSP) systems—to generate additional electricity. It can also be channeled into electrolysis chambers separating hydrogen from water when water is the used fluid or any other electrolysis processes that can be derived from the heated fluid. A hybrid system structure can also be installed to leverage advantages of each of the sub-components and further maximize overall output efficiency and return on investment (ROI).

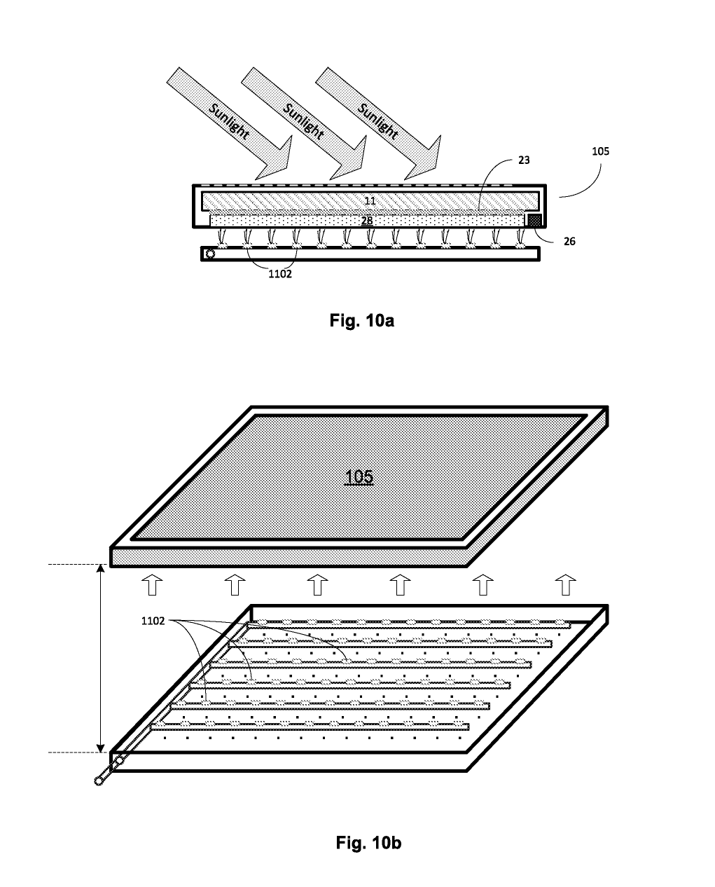

The fourth embodiment of this invention is an open loop design. An example of this fourth embodiment is shown in FIGS. 10a and 10b. The idea is to pump the water directly from a body of water (such as pond, lake or river), pass it through a system of fine jet nozzles 1102, and sprays the underside of the solar panel module 105 directly. Heat is conducted away mainly by water droplets vaporizing from the PV panel 11. Once the water is sprayed onto the PV panel 11, it drips back onto the ground and is lost. This is the reason it has to be an open loop design. The main advantage is that it is cheaper to implement than that for a heat exchanger, but the cooling efficiency may not be as high comparatively. Cooling efficiency can be optimized by controlling and applying the right incoming water pressure (PSI), flow rate and temperature variance tailored to a specific set of conditions.

In all the embodiments described above, electricity generated by the solar panel is more than sufficient to power all components of the GHE system. The direct current (DC) output of the solar farm will be converted to alternating current (AC), and transformed to the right voltage for running the pump, compressor, and expansion valve, etc, in the geothermal cooling loop. A self-sustaining operation can be created and realized without outside supply of any electric power.

The exemplary embodiments of the present invention are thus fully described. Although the description referred to particular embodiments, it will be clear to one skilled in the art that the present invention may be practiced with variation of these specific details. Hence this invention should not be construed as limited to the embodiments set forth herein.

For example, the main theme of this invention is to use the constant subterranean ground temperature, effectively unlimited heat capacity, to cool the array of PV panels operating above ground. While the preferred embodiment is for large scale Mega Watt solar farm, where this method is particularly efficient, the basic idea is equally applicable to roof mount off grid residential or commercial solar system, or even a single PV panel.

What is claimed is:

1. A closed-loop geothermal cooling system, using non-phase change heat transfer fluid to transport heat from an operating PV panel to subterranean level, comprising:
a) a heat sink mated securely and thermally to an underside of said PV panel by a thermal interface material; said heat sink further comprising a plurality of inlet and/or outlet connectors, and a plurality of built-in ducts;
b) a buried subterranean-level condenser comprising a plurality of vertical, horizontal or hybrid loops; and
c) a circulating pump adapted to power said heat transfer fluid around said loop.

2. The closed-loop geothermal cooling system of claim 1 wherein said non-phase change heat transfer fluid is an air-water mixture.

3. The closed-loop geothermal cooling system of claim 1 wherein said PV panel is made of a material selected from a group consisting of silicon, CdTe, or other semiconductors.

4. The closed-loop geothermal cooling system of claim 1 wherein said PV panel comprises sunlight concentrators.

5. A closed-loop geothermal cooling system, using phase change heat transfer fluid to transport heat from an operating PV panel to subterranean level, comprising:
a) a heat sink mated securely and thermally to an underside of said PV panel by a thermal interface material; said heat sink comprising a plurality of inlet and outlet connectors, and a plurality of built-in ducts;
b) a buried subterranean level condenser comprising a plurality of vertical or horizontal loops;
c) a compressor pump adapted to move the vaporized heat transfer fluid from said heat sink to said subterranean level condenser; and
d) an expansion valve adapted to reduce the pressure of said heat transfer fluid when said heat transfer fluid passes therethrough.

6. The closed-loop geothermal cooling system of claim 5 wherein said phase change heat transfer fluid is a refrigerant.

7. The closed-loop geothermal cooling system of claim 5 wherein said PV panel is made of a material selected from a group consisting of silicon, CdTe, or other semiconductors.

8. The closed-loop geothermal cooling system of claim 5 wherein said PV panel comprises sunlight concentrators.

9. The closed-loop geothermal cooling system of claim 5 wherein said heat sink is an evaporator.

10. A geothermal cooling system comprising:
a) a circulating pump adapted to pass water from a body of water to an array(s) of PV panels; and
b) a heat sink mated securely and thermally to an underside of said PV panel by a thermal interface material; said heat sink further comprising a plurality of inlet and/or outlet connectors, and a plurality of built-in ducts; said water transporting away the heat from said PV panels through said heat sink;
wherein said system is adapted to be used for a solar farm located in close proximity to said body of water; said system is operated under an open-loop or closed-loop design.

11. The geothermal cooling system of claim 10 wherein said heated water leaving said heat sink is channeled into stream chambers of stream turbines or electrolysis chambers.

12. The geothermal cooling system of claim 10 wherein said PV panel is made of a material selected from a group consisting of silicon, CdTe, or other semiconductors.

13. The closed-loop geothermal cooling system of claim 10 wherein said PV panel comprises sunlight concentrators.

14. A geothermal cooling system comprising:
a) a circulating pump adapted to pass cool water from a body of water to an array(s) of PV panels; and
b) a spray nozzle adapted to spray cool water onto a backside of said solar PV panels for transporting heat away from said solar PV panels;
wherein said system is adapted to be used for a solar farm located in close proximity to said body of water; said system is operated under an open design.

15. The geothermal cooling system of claim 14 wherein said PV panel is made of a material selected from a group consisting of silicon, CdTe, or other semiconductors.

16. The closed-loop geothermal cooling system of claim 14 wherein said PV panel comprises sunlight concentrators.
